(19) United States
(12) Patent Application Publication
(10) Pub. No.: US 2026/0237055 A1
(43) Pub. Date: Aug. 13, 2026

(54) METHOD FOR GENERATING SYNTHETIC DATA BASED ON GENERATIVE MODEL AND SYSTEM THEREFOR

(71) Applicant: NDOTLIGHT CO., LTD., Seongnam-si (KR)

(72) Inventor: Sun Tae KIM, Seongnam-si (KR)

(73) Assignee: NDOTLIGHT CO., LTD., Seongnam-si (KR)

(21) Appl. No.: 19/414,585

(22) Filed: Dec. 10, 2025

(30) Foreign Application Priority Data
Feb. 12, 2025 (KR) 10-2025-0017904

(51) Int. Cl. G06T 7/00; G06F 30/12; G06T 5/60; G06T 5/70; G06T 7/50

(52) U.S. Cl. CPC G06T 7/001; G06F 30/12; G06T 5/60; G06T 5/70; G06T 7/50; G06T 2207/20081; G06T 2207/20084; G06T 2207/30164

(57) ABSTRACT

Provided are a method for generating synthetic data based on a generative model and a system therefor. The method according to some embodiments may include obtaining data of a source shape and a target defect profile, extracting command information from the obtained data, extracting topology information of the source shape from the obtained data, and generating synthetic data of a defect shape in which the target defect profile is reflected in the source shape from the command information and the topology information by using the target defect profile as a condition of a generative model. According to the method, sophisticated synthetic defect data may be generated in a controllable manner, and a problem of securing anomaly data of a defect detection model may be effectively solved.

### CROSS-REFERENCE TO RELATED APPLICATION

This application claims priority to Korean Patent Application No. 10-2025-0017904, filed on Feb. 12, 2025, in the Korean Intellectual Property Office, the disclosure of which is incorporated herein by reference.

### BACKGROUND

### Field

The present disclosure relates to a technology for generating synthetic data using a generative model.

### Description of the Related Art

Anomaly detection is recognized as an important task in various industrial fields such as manufacturing, medicine, security, and finance, and a machine learning- or deep learning-based anomaly detection model is used as a powerful tool to effectively perform such a task. For example, the anomaly detection model is used to automatically detect a defect of a product in manufacturing, and is used to detect a disease early in the medical field.

However, when effectively training such an anomaly detection model, a significant amount of training sets is required, and securing anomaly data acts as a major challenge. This is because, generally, normal data may be easily secured, but anomaly data has a low frequency of occurrence, so it is realistically difficult to secure sufficient actual cases.

Since anomaly data is difficult to predict due to inherent characteristics thereof and exists in various forms, performance of the anomaly detection model inevitably deteriorates when sufficient data is not secured. Therefore, in order to construct a high-performance anomaly detection model, a method capable of generating anomaly data close to reality (so-called ‘data augmentation method’) is required. In particular, a method capable of generating various forms of anomaly data in a controllable manner is required so that the anomaly detection model may learn various types of anomaly patterns.

### SUMMARY

Therefore, the present disclosure has been made in view of the above problems, and it is an object of the present disclosure to provide a method for generating synthetic data and a system therefor.

It is another object of the present disclosure to provide a method for generating sophisticated synthetic data using a generative model and a system therefor. For example, the technical problem of the present disclosure is to provide a method for generating sophisticated synthetic data of an anomaly class such as defect shape data (e.g., 3D model data, a shape image, etc.) and a system therefor.

It is yet another object of the present disclosure to provide a method for generating various synthetic data by using a generative model in a controllable manner and a system therefor. For example, the technical problem of the present disclosure is to provide a method for accurately generating synthetic data of an anomaly class (e.g., defect shape data corresponding to a defect profile) according to a target anomaly profile and a system therefor.

The technical problems of the present disclosure are not limited to the technical problems mentioned above, and other technical problems not mentioned herein may be clearly understood by those skilled in the art to which the present disclosure pertains from the following description.

In accordance with one aspect of the present disclosure, provided is a method for generating at least one synthetic data, performed by at least one processor. The method may include: obtaining data of a source shape and a target defect profile; extracting command information from the obtained data, wherein the command information is regarding a command performed to generate the source shape; extracting topology information of the source shape from the obtained data; and generating synthetic data of a defect shape in which the target defect profile is reflected in the source shape from the command information and the topology information by using the target defect profile as a condition of a generative model.

In accordance with another aspect of the present disclosure, provided is a method for generating at least one synthetic data, performed by at least one processor. The method may include: obtaining data of a source shape and a target shape profile; extracting command information from the obtained data, wherein the command information is regarding a command performed to generate the source shape; extracting topology information of the source shape from the obtained data; and generating synthetic data of a target shape in which the target shape profile is reflected in the source shape from the command information and the topology information by using the target shape profile as a condition of a generative model.

In accordance with still another aspect of the present disclosure, provided is a system for generating at least one synthetic data. The system may include one or more processors; and a memory storing a computer program executed by the one or more processors, wherein the computer program may include instructions for: obtaining data of a source shape and a target defect profile; an operation of extracting command information from the obtained data, wherein the command information is regarding a command performed to generate the source shape; extracting topology information of the source shape from the obtained data; and generating synthetic data of a defect shape in which the target defect profile is reflected in the source shape from the command information and the topology information by using the target defect profile as a condition of a generative model.

In accordance with yet another aspect of the present disclosure, provided is a non-transitory computer-readable recording medium including instructions that, when executed by at least one processor, cause the at least one processor to perform a method for generating synthetic data. The method may include: obtaining data of a source shape and a target defect profile; extracting command information from the obtained data, wherein the command information is regarding a command performed to generate the source shape; extracting topology information of the source shape from the obtained data; and generating synthetic data of a defect shape in which the target defect profile is reflected in the source shape from the command information and the topology information by using the target defect profile as a condition of a generative model.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is an example diagram for explaining the operation of a synthetic data generation system at the system level according to some embodiments of the present disclosure;

FIG. 2 is an example diagram for further explaining the operation of the synthetic data generation system according to some embodiments of the present disclosure;

FIG. 3 is an example diagram for explaining a structure and an operation of a generative model according to some embodiments of the present disclosure;

FIG. 4 is an example diagram for explaining an operation method of a topology information extractor according to some embodiments of the present disclosure;

FIG. 5 is an example diagram for explaining a structure and an operation of a diffusion-based generator according to some embodiments of the present disclosure;

FIG. 6 is an example diagram for explaining a defect profile conditioning method and a denoising method according to some embodiments of the present disclosure;

FIG. 7 is an example diagram for explaining a defect profile conditioning method and a denoising method according to some other embodiments of the present disclosure;

FIG. 8 is an example diagram for explaining a defect profile conditioning method and a denoising method according to another embodiments of the present disclosure;

FIGS. 9A to 9D are example diagrams for explaining a defect profile conditioning method and a denoising method according to another embodiments of the present disclosure;

FIG. 10 is an example diagram for explaining an operation method of a discriminator according to some embodiments of the present disclosure;

FIG. 11 is an example diagram for explaining an operation method of a discriminator according to another embodiments of the present disclosure;

FIG. 12 is an example flowchart schematically illustrating a method for generating synthetic data according to some embodiments of the present disclosure;

FIG. 13 is an example diagram for further explaining a training set preparation step illustrated in FIG. 12;

FIG. 14 is an example diagram for further explaining a generative model construction step illustrated in FIG. 12;

FIG. 15 is an example flowchart showing a detailed process of a synthetic data generation step illustrated in FIG. 12; and

FIG. 16 illustrates an example computing device capable of implementing a synthetic data generation system according to some embodiments of the present disclosure.

### DETAILED DESCRIPTION

Hereinafter, various embodiments of the present disclosure are described in detail with reference to the attached drawings. The present disclosure will now be described more fully with reference to the accompanying drawings, in which example embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art. The present disclosure is defined only by the categories of the claims.

In addition, in the following description of the present disclosure, a detailed description of known functions and configurations incorporated herein will be omitted when it may make the subject matter of the present disclosure unclear.

Unless otherwise defined, terms used in the following embodiments (including technical and scientific terms) may be used with meanings commonly understood by those skilled in the art to which the present disclosure pertains, but this may vary depending on an intention of a technician working in a related field or a precedent, emergence of a new technology, and the like. Terms used in the present disclosure are for describing embodiments and are not intended to limit the scope of the present disclosure.

A singular expression used in the following embodiments includes a plural concept unless clearly specified as singular in context. In addition, a plural expression includes a singular concept unless clearly specified as plural in context.

In describing the components of the embodiments of the present disclosure, terms such as first, second, A, B, (a), and (b) may be used. These terms are used to distinguish each component from other components, and the nature or order of the components is not limited by these terms.

Components described with reference to terms such as part or unit, module, block, and ~or (~er) used in the following embodiments and functional blocks illustrated in the drawings may be implemented in the form of software, hardware, or a combination thereof. For example, the software may be machine code, firmware, embedded code, and application software. In addition, for example, the hardware may include electrical circuits, electronic circuits, processors, computers, integrated circuits, integrated circuit cores, passive elements, or a combination thereof.

Hereinafter, various embodiments of the present disclosure will be described in detail with reference to the accompanying drawings.

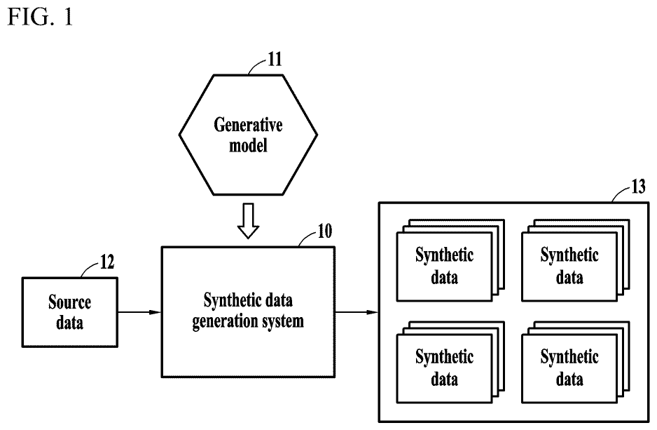

FIG. 1 is an example diagram for explaining the operation of a synthetic data generation system 10 at the system level according to some embodiments of the present disclosure.

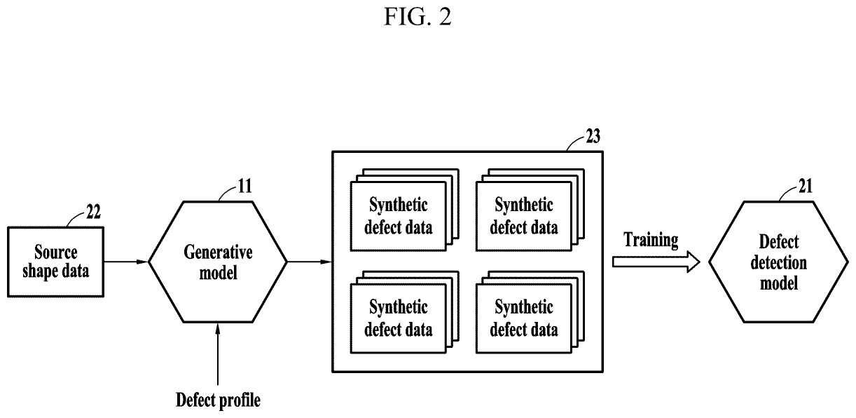

As shown in FIG. 1, the synthetic data generation system 10 is a computing device/system that may generate various synthetic data 13 from source data 12 using a generative model 11. For example, the synthetic data generation system 10 may generate various synthetic shape data from source shape (or geometry) data through the generative model 11. As a more specific example, the synthetic data generation system 10 may generate various synthetic defect data from source shape data using the generative model 11, and for details thereof, reference may be made to the description of FIG. 2 and the like.

The synthetic data generation system 10 may be referred to as a ‘data augmentation apparatus/system’, a ‘virtual data generation apparatus/system’, an ‘artificial data generation apparatus/system’, or a ‘defect/anomaly data generation apparatus/system’ in some cases, and may be abbreviated as a ‘data generation apparatus/system’.

Hereinafter, for convenience of understanding, the description will be continued assuming that the source data 12 is ‘data representing a shape’ of an object (e.g., a person, a thing, a product, etc.). However, the scope of the present disclosure is not limited thereto, and the technical spirit to be described later may be applied even when the source data 12 is other types of data.

In addition, hereinafter, for convenience of description, the synthetic data generation system 10 will be abbreviated as a ‘system’.

FIG. 2 is an example diagram for further explaining an operation of the system 10 according to some embodiments of the present disclosure.

As shown in FIG. 2, a system 10 may generate various synthetic defect data 23 from source shape data 22 through the generative model 11. For example, the system 10 may generate defect shape data in which a corresponding defect profile is reflected from normal shape data 22 (that is, data representing a shape without a defect) by using the defect profile as a condition of the generative model 11. In some cases, the system 10 may generate data of another shape (e.g., a shape in which a length, a width, a size, a bending, a ratio, a structure, etc. are modified) from the source shape data 22 by using a shape profile (or a transformation/deformation profile) as the condition of the generative model 11. Alternatively, the system 10 may generate shape data of another style from the source shape data 22 by using a style profile as the condition of the generative model 11.

The source shape data 22 is base data used to generate synthetic defect data, and refers to data representing (or expressing) a shape of a specific object as described above. Examples of such data may include data regarding a 2D model/shape and a 3D model/shape (e.g., 3D CAD, a 3D mesh model, a point cloud, etc.), an image (e.g., a 2D image, a 3D image, etc.), and the like, but the scope of the present disclosure is not limited thereto. In addition, examples of the 3D model data may include data such as command information for generating a 3D model/shape (e.g., a CAD command sequence performed to generate a specific shape at a user interaction level and a parameter value of each command), a boundary representation (B-rep), a point cloud, a mesh model, and the like, but the scope of the present disclosure is not limited thereto. The source shape data 22 may be regarded as the condition of the generative model 11, or may not be. The source shape data 22 may be actual data or synthetic data. For example, synthetic defect data generated through the generative model 11 may be used again as the source shape data 22.

The source shape data 22 may be referred to as ‘basic shape data’, ‘original shape data’, ‘reference shape data’, ‘input shape data’, or the like in some cases, and may be abbreviated as ‘source data’, ‘basic data’, or the like.

The defect profile is a set of information defining a shape defect, and is used to control an operation (or output) of the generative model 11. Here, examples of the shape defect may include wear, dent, hole, scratch, cut, distortion, warping, and the like, but the scope of the present disclosure is not limited thereto. The scope of the shape defect may include not only a surface defect but also a structural defect.

The defect profile may consist of one or more attributes representing the shape defect, and examples of such attributes may include a type, a weight (i.e., a degree/level/severity of the defect), a location, a direction, a size, and a shape of the defect, but the scope of the present disclosure is not limited thereto.

The defect profile may be referred to as an ‘anomaly profile’, ‘defect information’, a ‘shape profile’, a ‘control profile’, a ‘deformation/transformation profile’, or the like in some cases.

The synthetic defect data is synthetic data generated by reflecting the defect profile in the source shape data 22. In other words, the synthetic defect data may be understood as data representing a defect shape generated by reflecting the defect profile in a source shape. The synthetic defect data may be data of the same format as the source shape data 22 or data of a different format.

The synthetic defect data may be referred to as ‘synthetic shape data’, ‘defect shape data’, ‘target defect data’, or the like in some cases, and may be abbreviated as ‘defect data’, ‘synthetic data’, or the like.

The generative model 11 is a model having a data generation function, and is a model that receives the defect profile as a condition and generates the synthetic defect data from the source shape data 22. The generative model 11 may be a diffusion-based model and a conditional model, but the scope of the present disclosure is not limited thereto. In some cases, the generative model 11 may be implemented as a model of another method such as a variational autoencoder (VAE). Examples of the diffusion-based model may include a denoising diffusion probabilistic model (DDPM), a score-based generative model, and the like.

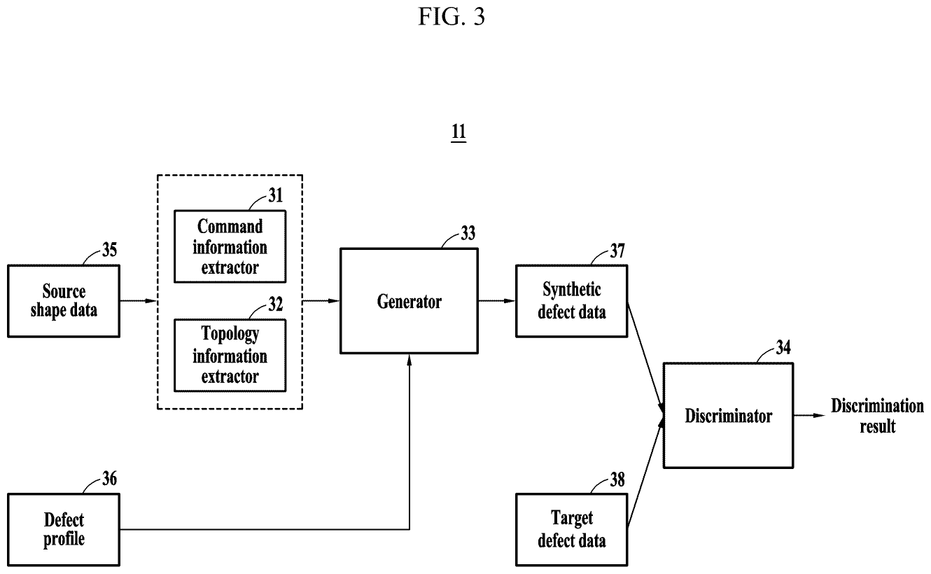

Details on a detailed structure, an operation, a training method, and the like of the generative model 11 will be described later with reference to FIG. 3 below.

The various synthetic defect data 23 generated from the source shape data 22 may be used to train (or construct) a defect detection model 21. In this case, the system 10 may generate various synthetic defect data 23 from the source shape data 22 while changing attribute values of a defect profile (e.g., values such as a type and a weight of a defect), and may further generate synthetic defect data using other source shape data. In addition, the system 10 may further generate synthetic defect data by using specific synthetic defect data as source shape data.

For example, when assuming that synthetic defect data is B-rep data (e.g., 3D model data in a B-rep format), the system 10 may render each of the synthetic defect data 23 to generate defect shape image samples, and add the samples to augment an existing training set (e.g., a training set composed of a plurality of normal shape image samples and a small number of defect shape image samples). Then, the system 10 may construct the defect detection model 21 using the augmented training set. By doing so, the high-performance defect detection model 21 may be easily constructed.

For reference, the term ‘sample’ may be used to refer to individual data of a data set (e.g., a training set) or to refer to individual data of a training step by distinguishing the data from an inference step.

In addition, some of the synthetic defect data 23 generated by the generative model 11 may be used as normal data samples when constructing the defect detection model 21. For example, when assuming that specific synthetic defect data is synthetic data of a shape in which only a minute defect exists (hereinafter referred to as a ‘minute defect shape’), and assuming that such a minute defect shape is determined as normal based on a defect determination criterion of an actual industry, synthetic data of the minute defect shape may be used as a normal data sample when constructing the defect detection model 21 (i.e., a normal label is assigned to an image sample of the minute defect shape). The synthetic data of the minute defect shape may be generated, for example, by setting a weight value of a defect profile to be less than or equal to a reference value, but the scope of the present disclosure is not limited thereto.

The above-described system 10 may be implemented using at least one computing device. For example, all functions of the system 10 may be implemented in one computing device, or a first function of the system 10 may be implemented in a first computing device and a second function may be implemented in a second computing device. Alternatively, a specific function of the system 10 may be implemented in a plurality of computing devices.

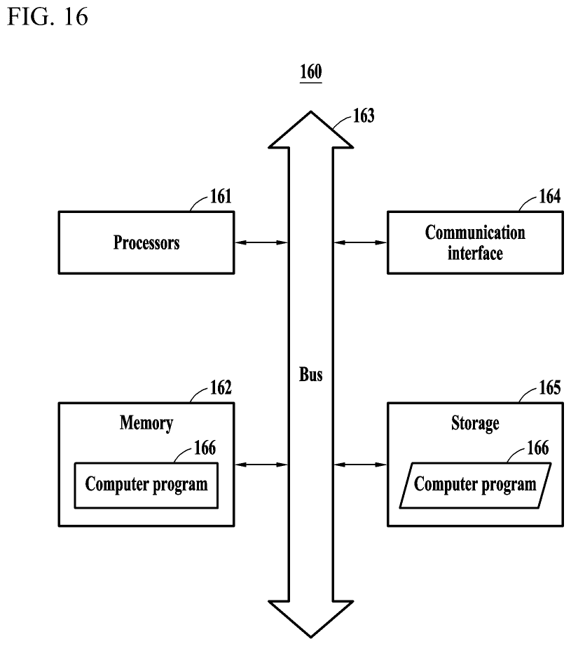

The computing device may encompass any device equipped with a computing function, and reference may be made to FIG. 16 for an example of such a device. Since the computing device is an aggregate in which various components (e.g., memory, processors, etc.) interact, the device may be referred to as a ‘computing system’ in some cases. Of course, the term computing system may also encompass a concept of an aggregate in which a plurality of computing devices interact.

So far, the operation of the system 10 according to some embodiments of the present disclosure has been described with reference to FIGS. 1 and 2. Hereinafter, a structure, an operation, and the like of the generative model 11 according to some embodiments of the present disclosure will be described in detail with reference to FIGS. 3 to 11.

FIG. 3 is an example diagram for explaining a structure and an operation of the generative model 11 according to some embodiments of the present disclosure. Blocks 31 to 34 illustrated in FIG. 3 may be understood as components of the system 10.

As shown in FIG. 3, the generative model 11 may be configured to include a command information extractor 31, a topology information extractor 32, a generator 33, and a discriminator 34. However, depending on a perspective, the command information extractor 31, the topology information extractor 32, and/or the discriminator 34 may not be regarded as components of the generative model 11.

The command information extractor 31 is a module that extracts command information from source shape data 35. As described above, the command information may include a command sequence performed to generate a specific shape at a user interaction level and a parameter value of each command.

For example, when a command history exists in the source shape data 35 (e.g., when the command history is a CAD file in which a command record is stored, etc.), the command information extractor 31 may extract the corresponding command history, and process the command history into an appropriate form as necessary.

As another example, the command information extractor 31 may extract command information by analyzing the source shape data 35. For example, the command information extractor 31 may analyze the source shape data 35 based on a predefined command description (or specification) to derive a command sequence and a parameter value of each command required to generate a source shape. In some cases, the command information extractor 31 may determine final command information by iteratively performing a step of deriving command information, a step of generating a temporary shape from the corresponding command information, a step of comparing the temporary shape with the source shape to identify a portion where a difference is equal to or greater than a reference value (e.g., a portion such as a face, an edge, etc.), and a step of correcting command information of the identified portion (e.g., iteratively performing until shape similarity becomes equal to or greater than a threshold).

As another example, the command information extractor 31 may extract command information based on various combinations of the above-described examples.

For types and parameters of commands used in CAD (Computer-Aided Design) tool, reference may be made to Table 1 below.

TABLE 1

| Commands | Description | Parameters |
|---|---|---|
| <SOL> | Start Of Loop | — |
| L(Line) | Line generation | x, y: Endpoint coordinates of a line |
| A(Arc) | Arc generation | x, y: Endpoint coordinates of an arc |
| | | α: Angle subtended by an arc |
| | | f: Flag indicating whether it is |
| | | counter-clockwise |
| R(Circle) | Circle generation | x, y: Center point coordinates of a circle |
| | | r: Radius of a circle |
| E(Extrude) | Extruding a 2D | θ, φ, γ: Orientations of a sketch plane |
| | shape into 3D | px, py, pz: Origins of a sketch plane |
| | | s: Scale of a sketch profile |
| | | e1, e2: Extrusion distances |
| | | b: Boolean type |
| | | u: Extrusion type |
| <EOS> | End Of command | — |
| | Sequence (End Of | |
| | whole Sequence) | |

Next, the topology information extractor 32 is a module that extracts topology information from the source shape data 35. The topology information extractor 32 may extract topology information of a source shape by analyzing the source shape data 35 in various ways. For example, the topology information extractor 32 may analyze the source shape data 35 to identify (or recognize) shape elements such as a face, an edge, and a vertex constituting the source shape and a connection relationship therebetween, and generate topology information from an identification result. When the source shape data 35 includes B-rep data, such shape elements may be easily identified from the B-rep data.

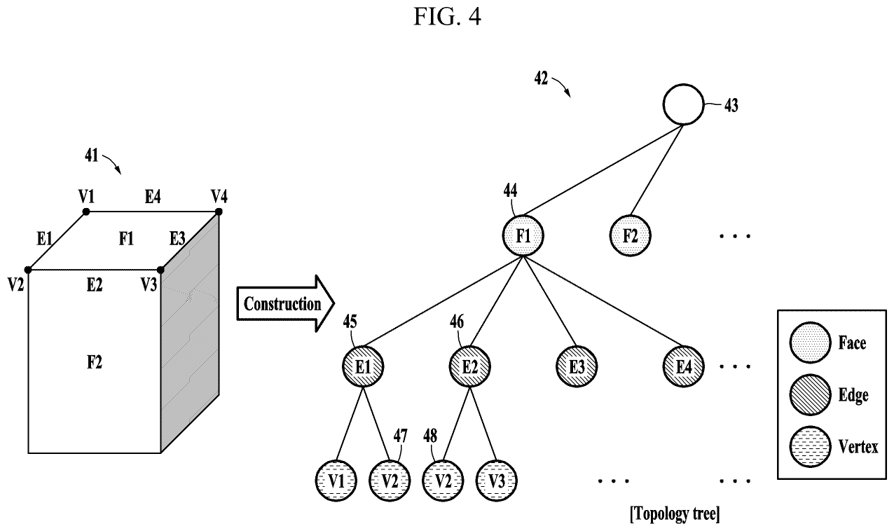

In some embodiments, the topology information extractor 32 may extract topology information through a process of hierarchically organizing elements of a source shape to construct (or build) a topology tree. For example, as shown in FIG. 4, the topology information extractor 32 may analyze the source shape data 35 to identify face, edge, and vertex elements constituting a source shape 41. Then, the topology information extractor 32 may map face (e.g., F1), edge (e.g., E1), and vertex elements (e.g., V1) to nodes (e.g., 44 to 48) of a first level, a second level, and a third level, respectively, to construct the topology tree 42 (for reference, a root node of a 0th level corresponds to the source shape 41). In this case, nodes of the topology tree 42 may be connected according to a connection relationship (or a topology/inclusion relationship) between elements constituting the source shape 41. Then, the topology information extractor 32 encodes geometric characteristic information (or feature information) of each face element to generate features of a mapping node (i.e., a face node), and may also generate features of a mapping node of each edge element (i.e., a line node) and a mapping node of each vertex element (i.e., a vertex node) in the same manner. Features of the node consist of, for example, location features (e.g., bounding box information) and shape features (however, features of the vertex node consist of only location features), and the shape features may be generated, for example, by encoding shape characteristic information of a shape element (e.g., using an encoder such as an autoencoder, a variational autoencoder (VAE), etc.), but the scope of the present disclosure is not limited thereto. For reference, when a specific vertex element (e.g., V2) or a specific edge element (e.g., E2) belongs to two or more upper shape elements, duplicate nodes (e.g., 47 and 48) occur in the topology tree 42, and such duplicate nodes may play a role of more clearly expressing a topology relationship of the source shape 41.

Description will be made with reference to FIG. 3 again.

A generator 33 is a module that receives command information and topology information of a source shape and a defect profile 36, and generates synthetic defect data 37 conforming to the defect profile 36. Each of the command information, the topology information, and the defect profile 36 may be embedded (or encoded) in an appropriate form and input to the generator 33.

The generator 33 may be implemented as, for example, a diffusion-based conditional model. However, the scope of the present disclosure is not limited thereto. For example, the generator 33 may be implemented based on a neural network such as UNet. However, hereinafter, for convenience of understanding, description will be continued assuming that the generator 33 is implemented as a ‘diffusion-based conditional model’. Examples of such a model include a conditional DDPM (Conditional DDPM), a conditional score-based generative model, and the like. Since those skilled in the art will already be familiar with operating principles of the conditional DDPM and the conditional score-based generative model, a description thereof will be omitted.

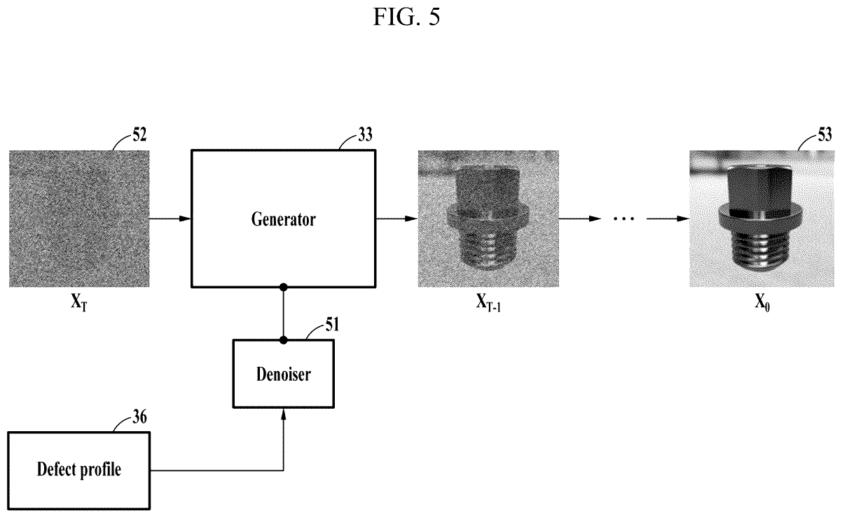

Hereinafter, a structure and an operation of the diffusion-based generator 33 will be further described with reference to FIGS. 5 to 8.

FIG. 5 is an example diagram for explaining a structure and an operation of the diffusion-based generator 33 according to some embodiments of the present disclosure. FIG. 5 and the like assume a case where the generator 33 is implemented as a conditional DDPM (or diffusion probabilistic model).

As shown in FIG. 5, the generator 33 may be configured to generate synthetic defect data 53 conforming to the defect profile 36 through a denoising process (or reverse process). However, in some cases, the generator 33 may generate intermediate synthetic defect data (e.g., a topology tree, command information, etc.) through the denoising process, and post-process the intermediate synthetic defect data to generate synthetic defect data (e.g., B-rep data, command information, a defect shape image, etc.).

The generator 33 may include a denoiser 51 that predicts noise at a specific time step to perform the denoising process. In addition, the defect profile 36 may be used as a condition of the generator 33 or the denoiser 51. Although not clearly illustrated in FIG. 5, command information and topology information of a source shape may also be used to generate the synthetic defect data 53. The synthetic defect data 53 may correspond to the synthetic defect data 37 of FIG. 3.

For reference, when the generator 33 is implemented as a conditional score-based generative model, the denoiser 51 may be replaced with a ‘score predictor’ which is a neural network predicting a score at a specific time step.

Specifically, the generator 33 may generate the high-quality synthetic defect data 53 from noise data 52 through a denoising process of repeatedly performing a step of predicting noise at a specific time step through the denoiser 51 and removing (or refining) the predicted noise. In this case, the noise data 52 may be generated by adding noise to at least one of the source shape data 35, command information, and topology information.

In FIG. 5 and the like, ‘X’ means data, a subscript means a time step, and ‘T’ means a maximum time step. In addition, in the denoising process, ‘X_{T}’ means noise data, and ‘X₀’ means synthetic data generated as a result of the process. In addition, FIG. 5 illustrates the generator 33 as generating an image, but this is merely for convenience of understanding, and the generator 33 may generate model data such as B-rep.

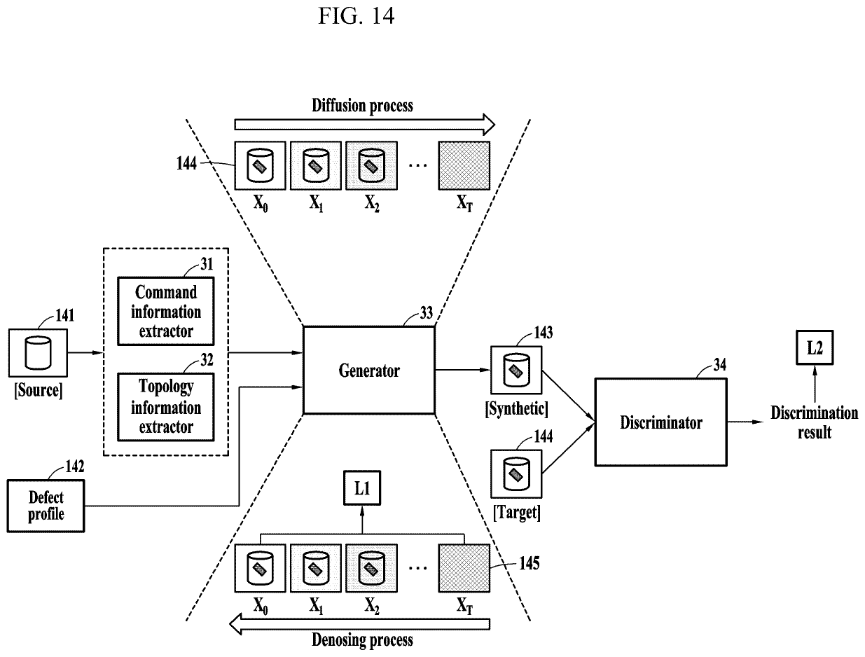

The denoiser 51 may be understood as a neural network that predicts noise of a specific time step. The denoiser 51 may be trained using noise added in a diffusion process (or forward process), and reference will be made to the description of FIG. 14.

The denoiser 51 may be referred to as a ‘noise predictor’, a ‘noise prediction neural network’, or the like in some cases.

Meanwhile, a specific method of conditioning the defect profile 36, a denoising method, and the like may vary depending on embodiments.

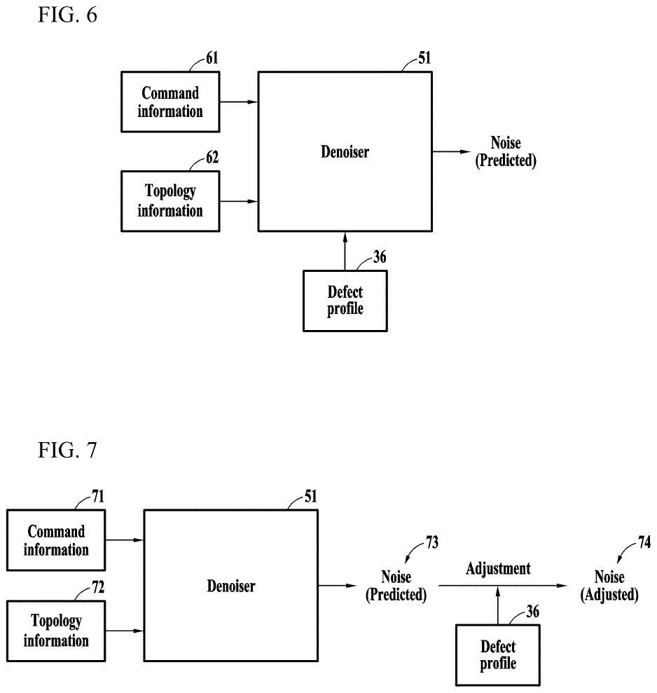

In some embodiments, as shown in FIG. 6, the defect profile 36 may be directly conditioned to the denoiser 51. That is, the defect profile 36 may be input to the denoiser 51 as a condition for predicting noise of a specific time step. For example, the denoiser 51 may be configured to receive command information 61, topology information 62, and the defect profile 36 and output prediction noise at a specific time step. In this case, noise for generating synthetic defect data may be accurately predicted. The denoiser 51 may be configured to further receive a value of a time step.

In another embodiment, as shown in FIG. 7, the defect profile 36 may be used to adjust prediction noise 73. Specifically, the denoiser 51 may be configured to receive command information 71 and topology information 72 and output the prediction noise 73 at a specific time step, and the defect profile 36 may be used to adjust the prediction noise 73. Adjustment of the prediction noise 73 may be performed, for example, through a neural network layer trained together with the denoiser 51 (e.g., a neural network layer that receives the prediction noise 73 and the defect profile 36 and outputs adjusted noise 74), but the scope of the present disclosure is not limited thereto. In these embodiments, the adjusted noise 74 may be used for a denoising operation instead of the prediction noise 73.

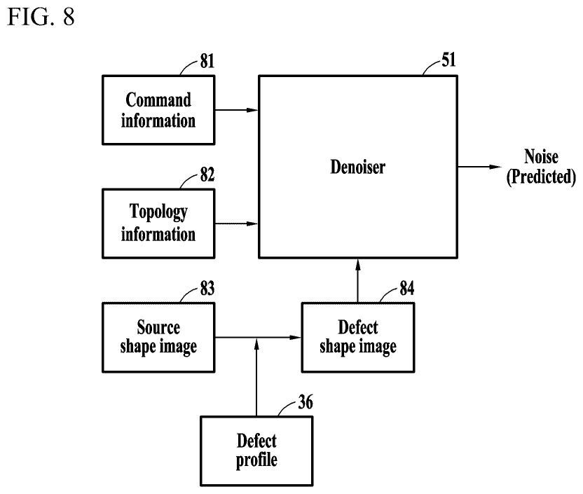

In another embodiment, as shown in FIG. 8, a source shape image 83 may be converted into a temporary defect shape image 84 by reflecting the defect profile 36. In some cases, the temporary defect shape image 84 (or defect shape data) may be generated by reflecting the defect profile 36 in the source shape data 35. The defect shape image 84 may be conditioned using the denoiser 51, and the denoiser 51 may be configured to receive command information 81, topology information 82, and the defect shape image 84 and output prediction noise. When the source shape data 35 is not an image, the source shape image 83 may be generated, for example, by rendering the source shape data 35. However, the scope of the present disclosure is not limited thereto. In addition, the source shape image 83 may be converted into the defect shape image 84 through, for example, a deep learning-based image conversion model, but the scope of the present disclosure is not limited thereto.

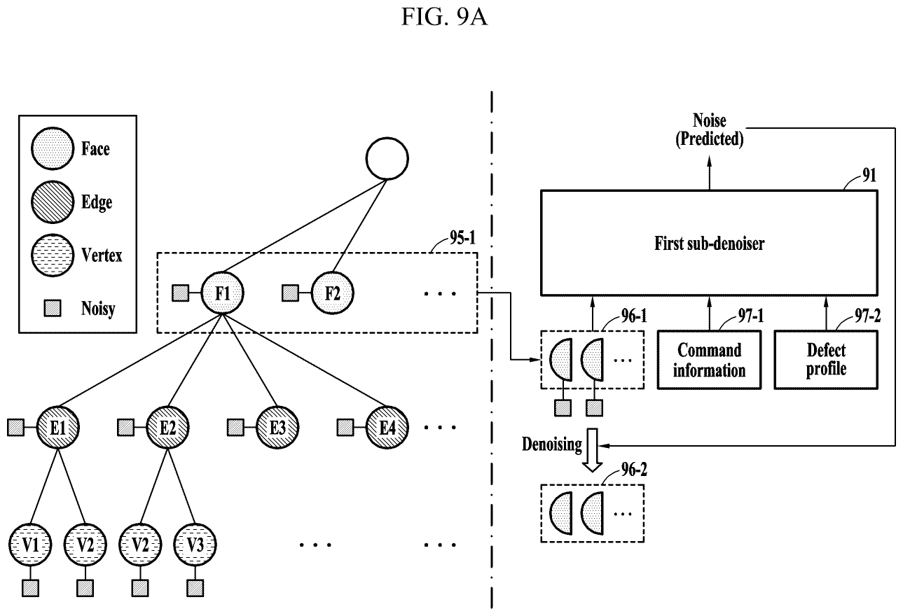

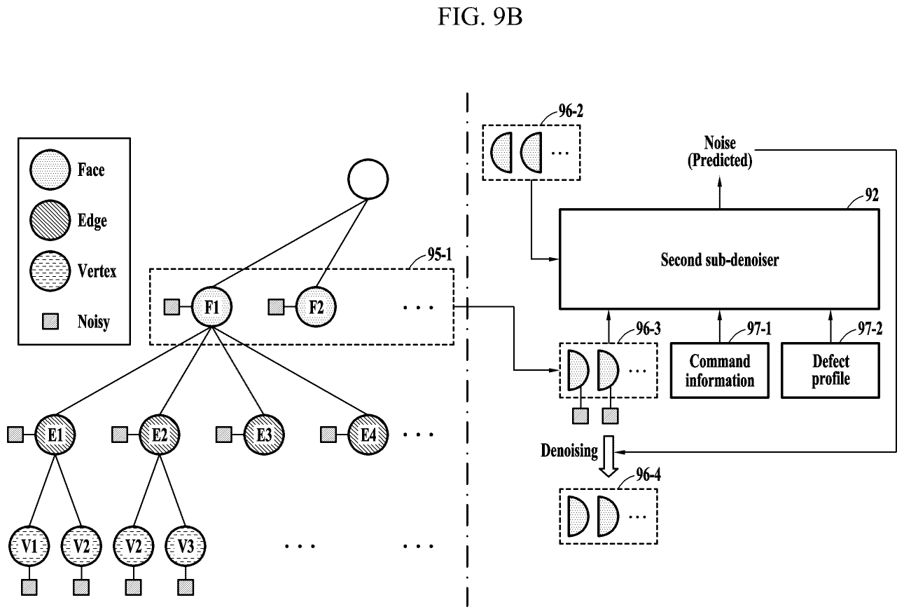

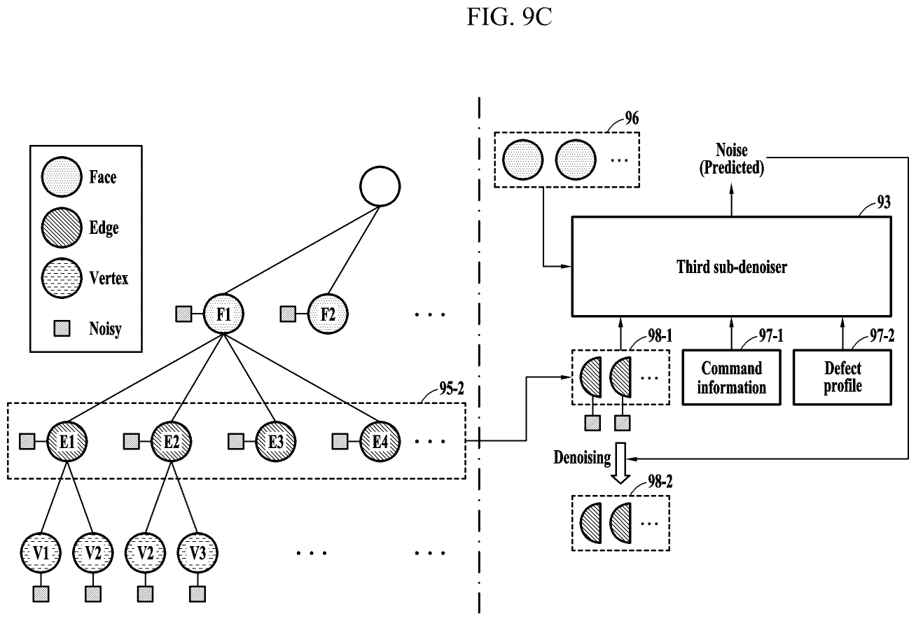

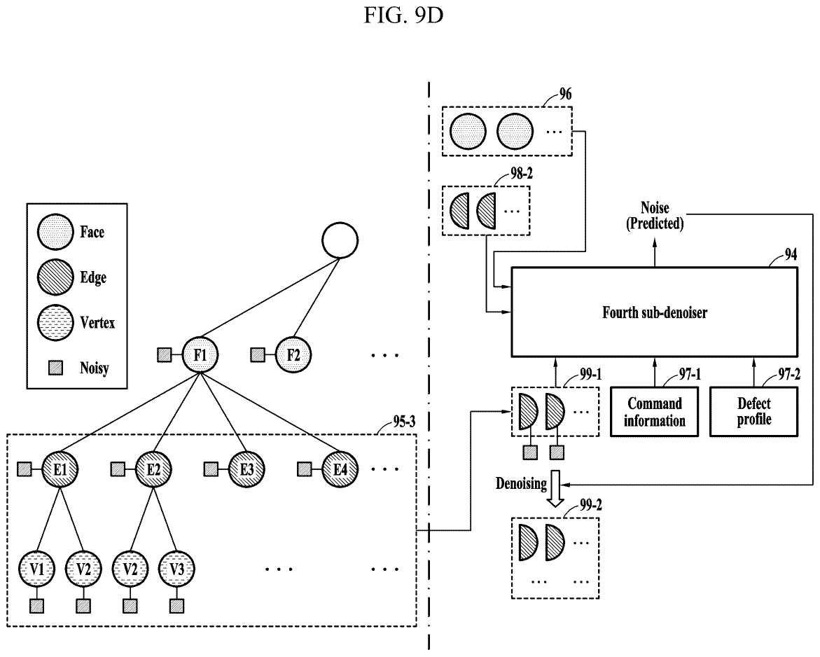

In another embodiment, as shown in FIGS. 9A to 9D, topology information may be configured in a tree form (refer to FIG. 4), and the denoiser 51 may be configured to include a plurality of sub-denoisers 91 to 94. In addition, a denoising operation at each time step may be sequentially proceeded (or performed) along a lower level direction of a topology tree through the sub-denoisers 91 to 94. The denoising operation will be further described below.

In another embodiment, the defect profile 36 may be conditioned or denoising may be performed based on various combinations of the above-described embodiments.

Hereinafter, a sequential denoising method will be further described with reference to FIGS. 9A to 9D.

FIGS. 9A to 9D are example diagrams showing a process in which a denoising operation proceeds sequentially according to some embodiments of the present disclosure. FIGS. 9A to 9D assume a case where node features of a topology tree consist of ‘location features’ and ‘shape features’ (however, node features of a vertex element consist of only location features), a topology tree is generated through a denoising process (i.e., the topology tree is intermediate synthetic defect data), and finally synthetic defect data (e.g., B-rep data) is generated through post-processing of the topology tree. However, the scope of the present disclosure is not limited thereto, and the number and type of detailed shape features constituting node features, resultant data of a denoising process, and the like may be variously designed.

As shown in FIGS. 9A to 9D, the denoiser 51 may be configured to include a plurality of sub-denoisers 91 to 94, and denoising may be performed along a lower level direction of a topology tree at every time step using the sub-denoisers 91 to 94. Each of the sub-denoisers 91 to 94 may be implemented based on a neural network.

Specifically, as shown in FIG. 9A, denoising may be performed on location features 96-1 of nodes at a face level 95-1 of a topology tree through a first sub-denoiser 91. The first sub-denoiser 91 may receive the noisy/noise location features 96-1, command information 97-1, and a defect profile 97-2, predict noise of a specific time step, and denoise the noisy/noise location features 96-1 using the noise.

Next, as shown in FIG. 9B, denoising may be performed on shape features 96-3 of nodes at the face level 95-1 of the topology tree through a second sub-denoiser 92. The second sub-denoiser 92 may receive denoised location features 96-2, noisy/noise shape features 96-3, the command information 97-1, and the defect profile 97-2, predict noise of a specific time step, and denoise the noisy/noise shape features 96-3 using the noise.

Next, as shown in FIG. 9C, denoising may be performed on location features 98-1 of nodes at an edge level 95-2 of the topology tree through a third sub-denoiser 93. A third sub-denoiser 93 may receive features 96 (that is, location features and shape features) of denoised face nodes, noisy/noise location features 98-1, the command information 97-1, and the defect profile 97-2, predict noise of a specific time step, and denoise the noisy/noise location features 98-1 using the noise.

Next, as shown in FIG. 9D, denoising may be performed on the remaining node features 99-1 (that is, shape features of edge nodes and location features of vertex nodes) of the edge level and a vertex level 95-3 of the topology tree through a fourth sub-denoiser 94. The fourth sub-denoiser 94 may receive features 96 (that is, location features and shape features) of denoised face nodes, location features 98-2 of denoised edge nodes, the noisy/noise node features 99-1, the command information 97-1, and the defect profile 97-2, predict noise of a specific time step, and denoise the noisy/noise node features 99-1 using the noise (refer to 99-2 for a denoising result).

Through the sequential denoising operation as described above, the topology tree in which the defect profile 97-2 is reflected and node features thereof may be accurately generated, and as a result, sophisticated synthetic defect data may be generated.

So far, the sequential denoising method according to some embodiments of the present disclosure has been described with reference to FIGS. 9A to 9D.

The description of the generator 33 will be continued with reference to FIG. 3 again.

In some embodiments, a weight for each of command information and topology information may be derived through a neural network layer. In addition, the command information and the topology information may be input to the generator 33 in a state where the weight is reflected. The neural network layer may be configured to receive the defect profile 36 and the source shape data 35 and output the weight of each of the command information and the topology information, and may be trained together with the generative model 11. In this case, the generator 33 becomes able to dynamically adjust a concentration on the command information and the topology information according to a source shape and the defect profile 36, and as a result, generation quality of the synthetic defect data 37 may be further improved.

Next, the discriminator 34 is a module performing a discrimination operation related to the synthetic defect data 37, and a specific discrimination method may vary depending on embodiments.

In some embodiments, the discriminator 34 may be configured to discriminate whether input synthetic defect data is synthetic or actual data. When the synthetic defect data is not an image, the discriminator 34 may receive a defect shape image generated by rendering the corresponding synthetic defect data, or may receive the corresponding synthetic defect data as is. Such technical contents may also be applied to other examples.

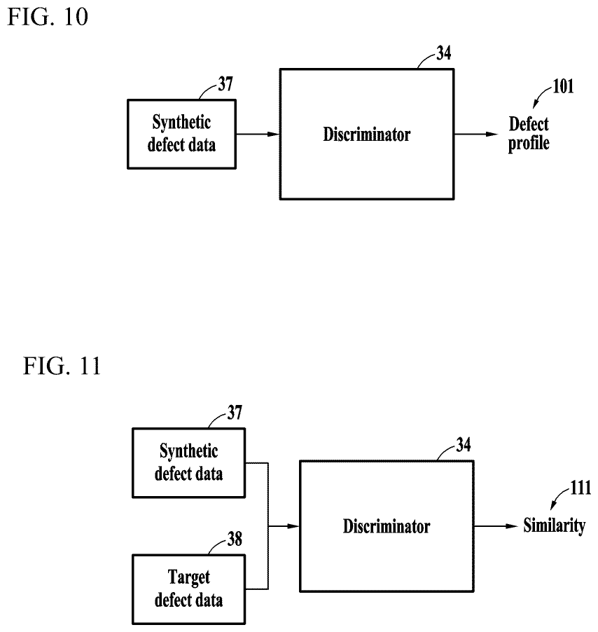

In other embodiments, as shown in FIG. 10, the discriminator 34 may be configured to discriminate a defect profile 101 (e.g., a type, a weight, etc. of a defect) of the input synthetic defect data 37.

In other embodiments, as shown in FIG. 3 or 11, the discriminator 34 may be configured to discriminate similarity 111 between the synthetic defect data 37 and target defect data 38 (hereinafter abbreviated as ‘target defect data’). Here, the target defect data 38 refers to defect shape data conforming to the defect profile 36, and may be understood as a kind of answer data. The discriminator 34 may receive the synthetic defect data 37 and the target defect data 38 together, or may not. For example, the discriminator 34 may discriminate a defect profile of the synthetic defect data 37, and derive the similarity by comparing the discriminated defect profile with the defect profile 36 of the target defect data 38.

In some cases, the discriminator 34 may be configured to output a similarity map in patch units. For example, the discriminator 34 may receive a synthetic defect shape image and a target defect shape image together, decompose and compare the synthetic defect shape image and the target defect shape image in patch units, and then output a similarity map. Such a similarity map provides direct information on an insufficient portion in the synthetic defect shape image, thereby further improving performance of the generator 33.

In other embodiments, the discriminator 34 may operate based on various combinations of the above-described embodiments.

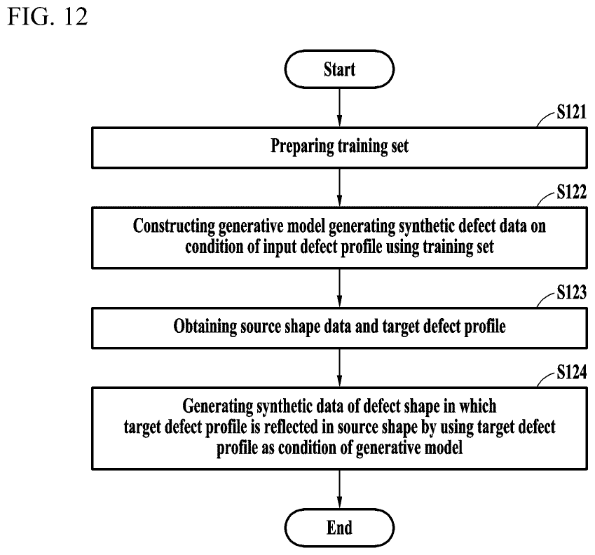

So far, the structure, the operation, and the like of the generative model 11 according to some embodiments of the present disclosure have been described with reference to FIGS. 3 to 11. Hereinafter, various methods capable of being performed in the above-described system 10 will be described with reference to FIG. 12 below.

Hereinafter, to provide convenience of understanding, the description will be continued assuming that all steps/operations of methods to be described later are performed in the above-described system 10. Therefore, when a subject of a specific step/operation is omitted, the corresponding step/operation may be understood as being performed in the system 10. However, in an actual environment, some steps/operations of the method to be described later may be performed in another computing device. For example, training of the generative model 11 may be performed in another computing device.

FIG. 12 is an example flowchart schematically illustrating a method for generating synthetic data according to some embodiments of the present disclosure. However, this is merely an example embodiment for achieving the object of the present disclosure, and some steps may be added or deleted as necessary. FIG. 12 assumes a case where the generated synthetic data is ‘defect shape data’.

As shown in FIG. 12, the method for generating synthetic data according to embodiments may start in step S121 of preparing a training set of the generative model 11.

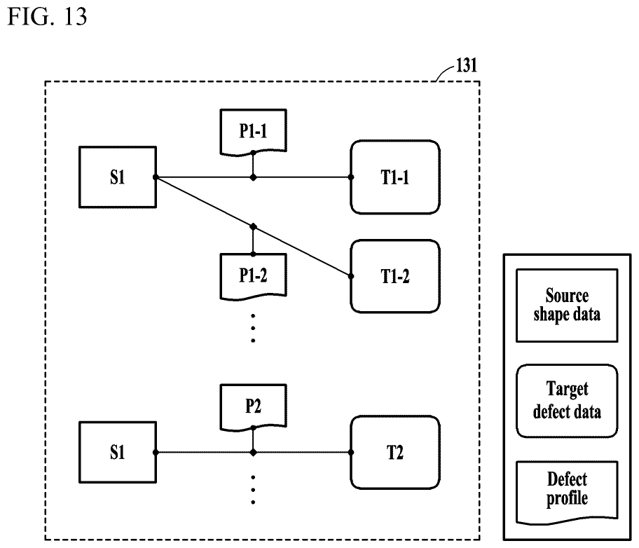

For example, as shown in FIG. 13, a training set 131 may consist of pairs of a source shape data sample (e.g., S1, hereinafter abbreviated as a ‘source shape sample’) and a target defect data sample (e.g., T2, hereinafter abbreviated as a ‘target defect sample’), and a source shape sample (e.g., S1) and target defect samples (e.g., T1-1, T1-2) may have a one-to-many relationship. The source shape sample (e.g., S1) may be a data sample representing (or expressing) a normal shape, but the scope of the present disclosure is not limited thereto. The training set 131 may further include a defect profile (e.g., P2) of the target defect sample (e.g., T2).

Description will be made with reference to FIG. 12 again.

In step S122, the generative model 11 that generates synthetic defect data on a condition of an input defect profile is constructed (or trained, built) using the training set. However, a specific training method and process may vary depending on a form of the generative model 11.

Hereinafter, for convenience of understanding, an example training process of the generative model 11 will be described with reference to FIG. 14.

FIG. 14 is an example diagram showing a training process of the generative model 11 according to some embodiments of the present disclosure. FIG. 14 assumes a case where the generative model 11 (precisely, the generator 33) is implemented based on a ‘conditional DDPM’. As shown in FIG. 14, the system 10 may train the generator 33 (precisely, the denoiser 51 of the generator 33) through a diffusion process and a denoising process.

Specifically, in the diffusion process, the system 10 may gradually noisify a target defect sample 144 by adding noise of a prior distribution (e.g., a Gaussian distribution) at every time step. In this case, the added noise may be used as ground truth noise for updating parameters of the denoiser 51.

In the denoising process, the system 10 may predict noise at each time step through the denoiser 51 and gradually denoise a noise data sample 145 using the predicted noise. In this case, the system 10 may predict the noise by using a defect profile 142 as a condition of the denoiser 51, and for this, reference may be made to the description of FIGS. 5 to 9D. Then, the system 10 may calculate a first loss (L1) representing a difference between prediction noise and the noise added in the diffusion process.

For reference, the noise data sample 145 may be generated by sampling from a prior distribution, or may be generated by adding noise of the prior distribution to at least one of a source shape sample 141, command information, and topology information. For example, when information/data in a topology tree format is generated through the denoising process, the noise data sample 145 may be generated by adding noise to the topology information. Similarly, when information/data in a command sequence format is generated, the noise data sample 145 may be generated by adding noise to the command information.

In addition, the system 10 may calculate a second loss (L2) according to similarity between a synthetic defect data sample 143 (hereinafter abbreviated as a ‘synthetic defect sample’) and the target defect sample 144 through the discriminator 34. Alternatively, the system 10 may determine whether the synthetic defect sample 143 corresponds to actual data through the discriminator 34, and calculate a loss according to a determination result.

In some cases, the system 10 may further calculate a third loss (e.g., a perceptual loss, a pixel level loss, etc.) by comparing the synthetic defect sample 143 and the target defect sample 144 at an image level or a feature level.

Next, the system 10 may update parameters of the generative model 11 based on the calculated losses (L1, L2). For example, the system 10 may calculate a total loss by adding up the losses (L1, L2), and update parameters of a generator 33 (precisely, the denoiser 51) based on the total loss.

The system 10 may repeat the above-described process for other source shape samples and target defect samples. By doing so, the generative model 11 capable of precisely controlling generation of synthetic defect data based on a defect profile may be constructed.

So far, the example training process of the generative model 11 has been described with reference to FIG. 14.

Description will be made with reference to FIG. 12 again.

In step S123, source shape data and a target defect profile are obtained. For example, the system 10 may receive the source shape data and the target defect profile from a user. As described above, the source shape data may be command information, model data such as B-rep, an image, or the like. In addition, the target defect profile may include, for example, information (or a value) regarding a type and a weight of a shape defect.

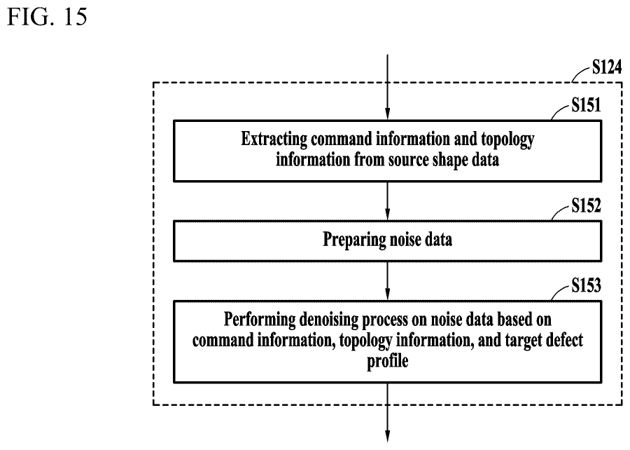

In step S124, synthetic data of a defect shape in which the target defect profile is reflected in the source shape is generated by using the target defect profile as a condition of the generative model 11. A detailed process of step S124 is illustrated in FIG. 15.

FIG. 15 is an example flowchart showing a detailed process of step S124. However, FIG. 15 is merely an example embodiment for achieving the object of the present disclosure, and some steps may be added or deleted as necessary. FIG. 15 assumes a case where a generative model 11 (precisely, the generator 33) is implemented based on a ‘conditional DDPM’.

In step S151, command information and topology information are extracted from source shape data. As described above, the command information may include a command sequence performed at a user interaction level to generate a source shape and a parameter value of each command. Since step S151 corresponds to operations of the command information extractor 31 and the topology information extractor 32, reference may be further made to descriptions of FIGS. 3 and 4.

In step S152, noise data is prepared. For example, the system 10 may sample the noise data from a prior distribution. As another example, the system 10 may generate the noise data by adding noise of the prior distribution to at least one of the source shape data, the command information, and the topology information. In this case, as information of the source shape is included in the noise data, sophisticated synthetic defect data in which characteristics of the source shape are well reflected may be generated.

In step S153, a denoising process is performed on the noise data based on the command information, the topology information, and the defect profile, and as a result, synthetic defect data is generated. However, a specific generation method thereof may vary depending on embodiments.

In some embodiments, the system 10 may input the command information, the topology information, and the defect profile to the denoiser 51 to predict noise of a specific time step, and denoise the noise data using the predicted noise. Such a denoising operation may be iteratively performed for other time steps. For these embodiments, reference may be further made to the description of FIG. 6.

In other embodiments, the system 10 may input the command information and the topology information to the denoiser 51 to predict noise of a specific time step, and adjust the predicted noise based on a target defect profile. Then, the system 10 may denoise the noise data using the adjusted noise. For these embodiments, reference may be further made to the description of FIG. 7.

In other embodiments, the system 10 may generate a temporary defect shape image based on the source shape data and the target defect profile, and input the command information, the topology information, and the defect shape image to the denoiser 51 to predict noise of a specific time step. Then, the system 10 may denoise the noise data using the predicted noise. For these embodiments, reference may be further made to the description of FIG. 8.

In other embodiments, the noise data is data in a form of a topology tree, and the system 10 may perform sequential denoising while moving in a lower level direction of the topology tree. For these embodiments, reference may be made to the description of FIGS. 9A to 9D.

In other embodiments, the denoising process may be performed based on various combinations of the above-described embodiments.

So far, the method for generating synthetic data according to some embodiments of the present disclosure has been described with reference to FIGS. 12 to 15. According to the above description, sophisticated synthetic data may be generated with high quality by using the diffusion-based generative model 11.

In addition, by generating synthetic defect data from the source shape data, a problem of securing anomaly data may be solved, and a high-performance defect detection model may be easily constructed. In addition, difficulty in securing a training set may be effectively solved in other anomaly detection fields as well.

In addition, by using the defect profile as the condition of the generative model 11, various synthetic defect data may be generated in a controllable manner. For example, by conditioning the defect profile including information on a type and a weight of a defect to the generative model 11, synthetic defect data having different types and degrees of defects may be freely generated.

In addition, by providing both the command information (i.e., information at the user interaction level) extracted from the source shape data and the topology information (i.e., information at the shape data level) to the generative model, high-quality synthetic defect data may be easily generated.

In addition, by constructing the topology tree in which a hierarchical relationship between shape elements is reflected from the source shape data, and generating node features of the topology tree based on geometric characteristic information of each shape element, the topology information of the source shape may be accurately extracted.

In addition, the above-described method for generating synthetic data may be utilized to generate other types of synthetic data in addition to defect synthetic data.

For example, the above-described method for generating synthetic data may be utilized to generate synthetic data of a target shape (e.g., a shape in which a length, a width, a size, a bending, a ratio, a structure, etc. are modified) from the source shape data by using a target shape profile as the condition of the generative model 11 (i.e., shape transformation/deformation may be performed using a shape profile instead of the defect profile). In this case, the generative model 11 may be constructed as described with reference to FIG. 14 using a training set consisting of a source shape data sample, a target shape data sample, and the shape profile. The shape profile may consist of attributes such as a type and a weight (i.e., a degree/level/intensity of deformation) of shape deformation (or the target shape), but the scope of the present disclosure is not limited thereto.

Hereinafter, an example computing device 160 capable of implementing the above-described system 10 will be described with reference to FIG. 16.

FIG. 16 is an example hardware configuration diagram showing the computing device 160.

As shown in FIG. 16, the computing device 160 may include one or more processors 161, a bus 163, a communication interface 164, a memory 162 that loads a computer program 166 executed by the processors 161, and a storage 165 that stores the computer program 166. However, only components related to the embodiment of the present disclosure are illustrated in FIG. 16. Therefore, those skilled in the art to which the present disclosure pertains will appreciate that other general-purpose components (e.g., input devices such as a keyboard and a mouse, output devices such as a speaker and a display) may be further included in addition to the components illustrated in FIG. 16. That is, the computing device 160 may further include various components in addition to the components illustrated in FIG. 16. In addition, in some cases, the computing device 160 may be configured in a form in which some of the components illustrated in FIG. 16 are omitted. Hereinafter, each component of the computing device 160 will be described.

The processors 161 may control overall operations of each configuration of the computing device 160. The processors 161 may be configured to include at least one of a Central Processing Unit (CPU), a Micro Processor Unit (MPU), a Micro Controller Unit (MCU), a Graphic Processing Unit (GPU), a Neural Processing Unit (NPU), a Tensor Processing Unit (TPU), a Vision Processing Unit (VPU), an Accelerated Processing Unit (APU), or processors of any form well known in the technical field of the present disclosure. In addition, the processors 161 may perform an operation on at least one application or program for executing specific operations/steps/methods. The computing device 160 may be equipped with one or more processors.

Next, the memory 162 may store various data, instructions, and/or information. The memory 162 may load the computer program 166 from the storage 165 to execute specific operations/steps/methods. The memory 162 may be implemented as a volatile memory such as a RAM, but the technical scope of the present disclosure is not limited thereto.

Next, the bus 163 may provide a communication function between components of the computing device 160. The bus 163 may be implemented as various types of buses such as an address bus, a data bus, and a control bus.

Next, the communication interface 164 may support wired/wireless Internet communication of the computing device 160. In addition, the communication interface 164 may support various communication methods other than Internet communication. To this end, the communication interface 164 may be configured to include a communication module well known in the technical field of the present disclosure.

Next, the storage 165 may non-transitorily store one or more computer programs 166. The storage 165 may be configured to include a non-volatile memory such as a Read Only Memory (ROM), an Erasable Programmable ROM (EPROM), an Electrically Erasable Programmable ROM (EEPROM), and a flash memory, a hard disk, a removable disk, or a computer-readable recording medium of any form well known in the technical field to which the present disclosure pertains.

Next, the computer program 166 may include instructions that cause the processors 161 to perform specific operations/steps/methods when loaded into the memory 162. That is, the processors 161 may perform specific operations/steps/methods by executing the loaded instructions.

For example, the computer program 166 may include instructions for an operation of obtaining data of a source shape and a target defect profile, an operation of extracting command information from the obtained data, an operation of extracting topology information of the source shape from the obtained data, and an operation of generating synthetic data of a defect shape in which the target defect profile is reflected in the source shape from the command information and the topology information by using the target defect profile as a condition of the generative model 11.

As another example, the computer program 166 may include instructions for an operation of obtaining data of a source shape and a target shape profile, an operation of extracting command information from the obtained data, an operation of extracting topology information of the source shape from the obtained data, and an operation of generating synthetic data of a target shape in which the target shape profile is reflected in the source shape from the command information and the topology information by using the target shape profile as a condition of the generative model 11.

As another example, the computer program 166 may include instructions for causing at least some of the operations/steps/methods described with reference to FIGS. 1 to 15 to be performed.

In the illustrated case, the system 10 according to some embodiments of the present disclosure may be implemented through the computing device 160.

In addition, in some embodiments, the computing device 160 illustrated in FIG. 16 may mean a virtual machine implemented based on cloud technology. For example, the computing device 160 may be a virtual machine operating on one or more physical servers included in a server farm. In this case, at least some of the processors 161, the memory 162, and the storage 165 illustrated in FIG. 16 may be virtual hardware, and the communication interface 164 may also be implemented as a virtualized networking element such as a virtual switch.

So far, the example computing device 160 capable of implementing a treatment support system according to some embodiments of the present disclosure has been described with reference to FIG. 16.

So far, the example computing device 160 capable of implementing the system 10 according to some embodiments of the present disclosure has been described with reference to FIG. 16.

So far, various embodiments of the present disclosure and effects according to the embodiments have been mentioned with reference to FIGS. 1 to 16. Effects according to the technical spirit of the present disclosure are not limited to the effects mentioned above, and other effects not mentioned herein may be clearly understood by those skilled in the art from the following description.

In accordance with one aspect of the present disclosure, provided is a method for generating at least one synthetic data, performed by at least one processor. The method may include: obtaining data of a source shape and a target defect profile; extracting command information from the obtained data, wherein the command information is regarding a command performed to generate the source shape; extracting topology information of the source shape from the obtained data; and generating synthetic data of a defect shape in which the target defect profile is reflected in the source shape from the command information and the topology information by using the target defect profile as a condition of a generative model.

In some embodiments, the obtained data may be CAD data, and the command information may include a CAD command sequence performed at a user interaction level.

In some embodiments, the target defect profile may include information regarding a type and a weight of a shape defect.

In some embodiments, the extracting of topology information may include constructing a topology tree by mapping a face element, an edge element, and a vertex element constituting the source shape to a node of a first level, a node of a second level, and a node of a third level, respectively, wherein the second level is a lower level of the first level, and the third level is a lower level of the second level; generating a first feature of the node of the first level by encoding geometric characteristic information of the face element; generating a second feature of the node of the second level by encoding geometric characteristic information of the edge element; and generating a third feature of the node of the third level by encoding geometric characteristic information of the vertex element.

In some embodiments, the generative model may be a diffusion-based model, and the generating of the synthetic data may include: preparing noise data; and performing a denoising process on the noise data based on the command information, the topology information, and the target defect profile.

In some embodiments, the preparing of the noise data may include: generating the noise data by adding noise to at least one of the obtained data, the command information, and the topology information.

In some embodiments, the performing of the denoising process may include: predicting noise of a specific time step by inputting the command information, the topology information, and the target defect profile into a neural network-based denoiser; and denoising the noise data using the predicted noise.

In some embodiments, the performing of the denoising process may include: predicting noise of a specific time step by inputting the command information and the topology information into a neural network-based denoiser; adjusting the predicted noise based on the target defect profile; and denoising the noise data using the adjusted noise.

In some embodiments, the performing of the denoising process may include: generating a defect shape image in which the target defect profile is reflected in the source shape based on the obtained data and the target defect profile; predicting noise of a specific time step by inputting the command information, the topology information, and the defect shape image into a neural network-based denoiser; and denoising the noise data using the predicted noise.

In some embodiments, the target defect profile may include information regarding a type and a weight of a defect, and the generating of the synthetic data may include generating a plurality of synthetic data while changing values of the type and the weight.

In some embodiments, the plurality of the synthetic data may be used to construct a defect detection model.

In some embodiments, a training process of the generative model may include: generating a synthetic defect data sample from a source shape data sample according to a specified defect profile; discriminating a defect profile of the synthetic defect data sample through a discriminator; and updating parameters of the generative model using a loss based on a result of the discriminating.

In some embodiments, a training process of the generative model may include: generating a synthetic defect data sample from a source shape data sample according to a specified defect profile; obtaining a target defect data sample corresponding to the specified defect profile; discriminating similarity between the synthetic defect data sample and the target defect data sample through a discriminator; and updating parameters of the generative model using a loss based on a result of the discriminating.

In accordance with another aspect of the present disclosure, provided is a method for generating at least one synthetic data, performed by at least one processor. The method may include: obtaining data of a source shape and a target shape profile; extracting command information from the obtained data, wherein the command information is regarding a command performed to generate the source shape; extracting topology information of the source shape from the obtained data; and generating synthetic data of a target shape in which the target shape profile is reflected in the source shape from the command information and the topology information by using the target shape profile as a condition of a generative model.

In accordance with still another aspect of the present disclosure, provided is a system for generating at least one synthetic data. The system may include one or more processors; and a memory storing a computer program executed by the one or more processors, wherein the computer program may include instructions for: obtaining data of a source shape and a target defect profile; an operation of extracting command information from the obtained data, wherein the command information is regarding a command performed to generate the source shape; extracting topology information of the source shape from the obtained data; and generating synthetic data of a defect shape in which the target defect profile is reflected in the source shape from the command information and the topology information by using the target defect profile as a condition of a generative model.

In accordance with yet another aspect of the present disclosure, provided is a non-transitory computer-readable recording medium including instructions that, when executed by at least one processor, cause the at least one processor to perform a method for generating synthetic data. The method may include: obtaining data of a source shape and a target defect profile; extracting command information from the obtained data, wherein the command information is regarding a command performed to generate the source shape; extracting topology information of the source shape from the obtained data; and generating synthetic data of a defect shape in which the target defect profile is reflected in the source shape from the command information and the topology information by using the target defect profile as a condition of a generative model.

According to some embodiments of the present disclosure, various synthetic data may be easily generated from source data by using a generative model. For example, sophisticated synthetic data may be generated with high quality by using a diffusion-based generative model.

In addition, a problem of securing anomaly data may be solved by generating synthetic defect data from source shape data, and a high-performance defect detection model may be easily constructed. In addition, difficulty in securing a training set may be effectively solved in other anomaly detection fields.

In addition, various synthetic defect data may be generated in a controllable manner by using a defect profile as a condition of a generative model. For example, synthetic defect data having different types and degrees of defects may be freely generated by conditioning a defect profile including information on a type and a weight of a defect to the generative model.

In addition, high-quality synthetic defect data may be easily generated by providing both command information (i.e., information at a user interaction level) and topology information (i.e., information at a shape data level) extracted from source shape data to the generative model.

In addition, topology information of a source shape may be accurately extracted by constructing a topology tree in which a hierarchical relationship between shape elements is reflected from source shape data, and generating node features of the topology tree based on geometric characteristic information of each shape element.

Effects according to the technical spirit of the present disclosure are not limited to the effects mentioned above, and other effects not mentioned herein may be clearly understood by those skilled in the art from the above description.

In addition, even when a plurality of components are described as being combined into one or operating in combination in the above-described embodiments, the technical spirit of the present disclosure is not necessarily limited to such embodiments. That is, within a scope of an object of the technical spirit of the present disclosure, all of the components may operate by being selectively combined into one or more.

The technical spirit of the present disclosure described so far may be implemented as computer-readable codes on a computer-readable recording medium. The computer program recorded on the computer-readable recording medium may be transmitted to another computing device through a network such as the Internet and installed in the computing device, and thereby may be used in the computing device.

Although operations are shown in a specific order in the drawings, the operations should not be understood as having to be performed in the specific order shown or in a sequential order, or that all shown operations must be performed to obtain a desired result. In a specific situation, multitasking and parallel processing may be advantageous. Although various embodiments of the present disclosure have been described with reference to the accompanying drawings, those skilled in the art to which the present disclosure pertains may understand that the technical spirit of the present disclosure may be implemented in other specific forms without changing the technical spirit or essential features thereof. Therefore, the embodiments described above should be understood as illustrative in all respects and not limiting. A protection scope of the present disclosure should be interpreted by the following claims, and all technical spirits within an equivalent scope thereof should be interpreted as being included in a scope of rights of the technical spirit defined by the present disclosure.

What is claimed is:

1. A method for generating at least one synthetic data, performed by at least one processor, the method comprising:
obtaining data of a source shape and a target defect profile;
extracting command information from the obtained data, wherein the command information comprises command sequence at a user-interaction level performed to generate the source shape;
extracting topology information of the source shape from the obtained data; and
generating synthetic data of a defect shape in which the target defect profile is reflected in the source shape from the command information and the topology information by using the target defect profile as a condition of a generative model.

2. The method according to claim 1, wherein the obtained data is CAD data, and the command information comprises the command sequence performed in a CAD tool.

3. The method according to claim 1, wherein the target defect profile comprises information regarding a type of a shape defect and a weight indicating a degree of the shape defect.

4. The method according to claim 1, wherein the extracting of the topology information comprises:
constructing a topology tree by mapping a face element, an edge element, and a vertex element constituting the source shape to a node of a first level, a node of a second level, and a node of a third level, respectively, wherein the second level is a lower level of the first level, and the third level is a lower level of the second level;
generating a first feature of the node of the first level by encoding geometric characteristic information of the face element;
generating a second feature of the node of the second level by encoding geometric characteristic information of the edge element; and
generating a third feature of the node of the third level by encoding geometric characteristic information of the vertex element.

5. The method according to claim 1, wherein the generative model is a diffusion-based model, and
the generating of the synthetic data comprises:
preparing noise data; and
performing a denoising process on the noise data based on the command information, the topology information, and the target defect profile.

6. The method according to claim 5, wherein the preparing of the noise data comprises generating the noise data by adding noise to at least one of the obtained data, the command information, and the topology information.

7. The method according to claim 5, wherein the performing of the denoising process comprises:
predicting noise of a specific time step by inputting the command information, the topology information, and the target defect profile into a neural network-based denoiser; and
denoising the noise data using the predicted noise.

8. The method according to claim 5, wherein the performing of the denoising process comprises:
predicting noise of a specific time step by inputting the command information and the topology information into a neural network-based denoiser;
adjusting the predicted noise based on the target defect profile; and
denoising the noise data using the adjusted noise.

9. The method according to claim 5, wherein the performing of the denoising process comprises:
generating a defect shape image in which the target defect profile is reflected in the source shape based on the obtained data and the target defect profile;
predicting noise of a specific time step by inputting the command information, the topology information, and the defect shape image into a neural network-based denoiser; and
denoising the noise data using the predicted noise.

10. The method according to claim 1, wherein the target defect profile comprises information regarding a type of a shape defect and a weight indicating a degree of the shape defect, and
the generating of the synthetic data comprises generating a plurality of synthetic data while changing values of the type and the weight.

11. The method according to claim 10, wherein the plurality of the synthetic data is used to construct a defect detection model.

12. The method according to claim 1, wherein a training process of the generative model comprises:
generating a synthetic defect data sample from a source shape data sample according to a specified defect profile;
discriminating a defect profile of the synthetic defect data sample through a discriminator; and
updating parameters of the generative model using a loss based on a result of the discriminating.

13. The method according to claim 1, wherein a training process of the generative model comprises:
generating a synthetic defect data sample from a source shape data sample according to a specified defect profile;
obtaining a target defect data sample corresponding to the specified defect profile;
discriminating similarity between the synthetic defect data sample and the target defect data sample through a discriminator; and
updating parameters of the generative model using a loss based on a result of the discriminating.

14. A method for generating at least one synthetic data, performed by at least one processor, the method comprising:
obtaining data of a source shape and a target shape profile;
extracting command information from the obtained data, wherein the command information comprises command sequence at a user-interaction level performed to generate the source shape;
extracting topology information of the source shape from the obtained data; and
generating synthetic data of a target shape in which the target shape profile is reflected in the source shape from the command information and the topology information by using the target shape profile as a condition of a generative model.

15. A system for generating at least one synthetic data, the system comprising:
one or more processors; and
a memory storing a computer program executed by the one or more processors,
wherein the computer program comprises instructions for:
obtaining data of a source shape and a target defect profile;
extracting command information from the obtained data, wherein the command information comprises command sequence at a user-interaction level performed to generate the source shape;
extracting topology information of the source shape from the obtained data; and
generating synthetic data of a defect shape in which the target defect profile is reflected in the source shape from the command information and the topology information by using the target defect profile as a condition of a generative model.

16. The system according to claim 15, wherein the generative model is a diffusion-based model, and
the generating of the synthetic data comprises:
preparing noise data; and
performing a denoising process on the noise data based on the command information, the topology information, and the target defect profile.
